(19) United States
(12) Patent Application Publication
(10) Pub. No.: US 2022/0190029 A1
(43) Pub. Date: Jun. 16, 2022

(54) TIER ARCHITECTURE FOR 3-DIMENSIONAL CROSS POINT MEMORY

(71) Applicant: Intel Corporation, Santa Clara, CA (US)

(72) Inventors: Derchang Kau, Cupertino, CA (US); Prashant Majhi, San Jose, CA (US); Khaled Hasnat, San Jose, CA (US)

(73) Assignee: Intel Corporation, Santa Clara, CA (US)

(21) Appl. No.: 17/118,367

(22) Filed: Dec. 10, 2020

(51) Int. Cl. H01L 27/24; H01L 45/00

(52) U.S. Cl. CPC H01L 27/249; H01L 45/1683; H01L 27/2409

(57) ABSTRACT

A memory structure includes a plurality of memory cells between a first and a second terminal and a pair of first conductors within a first tier, where individual ones of the first conductors are coupled to the first terminal of a first adjacent pair of memory cells in a first row orthogonal to the first conductors. The memory structure further includes a pair of second conductors within a second tier and parallel to the first conductors, where individual ones of the second conductors are coupled to the first terminal of a second adjacent pair of memory cells in a second row. The memory structure further includes a third conductor between the first and second tiers, and between each of the pair of the first conductors and the pair of the second conductors. The third conductor is coupled to second terminals of both the first and second adjacent pairs of memory cells.

### BACKGROUND

A three-dimensional (3-D) cross point memory array may have tiers, or decks, of memory cells. However, increasing a total number of memory cells in this manner may proportionately increase the number of decoder transistors needed, thereby increasing an overall footprint of the decoder transistors. As such, solutions are required to increase memory density while minimizing decoder transistor footprint.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A is a cross-sectional illustration of a memory device structure with a tiered memory array

FIG. 1B is an isometric illustration of the memory device structure in FIG. 1A.

FIG. 1C is an isometric illustration of a lower memory tier.

FIG. 1D is a cross sectional illustration through the line A-A′ in FIG. 1B.

FIG. 2A is a cross-sectional illustration of a memory element, in accordance with an embodiment of the present disclosure.

FIG. 2B is a cross-sectional illustration of a selector element, in accordance with an embodiment of the present disclosure.

FIG. 2C is a cross-sectional illustration of a selector element, in accordance with an embodiment of the present disclosure.

FIG. 2D is a cross-sectional illustration of a built-in memory selector cell, where an insulator layer exhibits memory element and selector element characteristics.

FIG. 2E is a cross-sectional illustration of a switching layer adjacent to an insulator layer in a memory cell, in accordance with an embodiment of the present disclosure.

FIG. 2F is a cross-sectional illustration of a memory cell, in accordance with an embodiment of the present disclosure.

FIG. 3 is a method to fabricate a memory cell array described in association with FIGS. 1A-1C, in accordance with an embodiment of the present disclosure.

FIG. 4A illustrates a material layer stack formed above a substrate.

FIG. 4B is a cross-sectional illustration of the structure in FIG. 4A following the process to mask and etch to form a staircase structure.

FIG. 4C is a cross-sectional illustration of a portion of the material layer stack in FIG. 4B, following the process to etch and form plurality of openings.

FIG. 4D illustrates the structure of FIG. 4C following a process to selectively laterally recess portions of a dielectric to form a plurality of recesses.

FIG. 4E illustrates the structure of FIG. 4D following the formation of an electrode material in the plurality of lateral recesses.

FIG. 4F illustrates the structure of FIG. 4E following the process to etch and remove portions of the electrode material from the plurality of openings and from portions of lateral recesses.

FIG. 4G illustrates the structure of FIG. 4F following the deposition of a selector material in the plurality of recesses adjacent to the electrode material.

FIG. 4H illustrates the structure of FIG. 4G following the process to etch and remove portions of the selector material from portions of lateral recesses adjacent to the electrode material.

FIG. 4I illustrates the structure of FIG. 4H following the formation of electrode material adjacent to the selector material.

FIG. 4J illustrates the structure of FIG. 4I following the deposition of one or more layers of memory material in the plurality of recesses adjacent to the electrode material.

FIG. 4K illustrates the structure of FIG. 4J following the process to etch and remove portions of the memory material and from portions of lateral recesses adjacent to electrode material.

FIG. 4L illustrates the structure of FIG. 4K following the formation of electrode material adjacent to the memory material.

FIG. 5A illustrates the structure of FIG. 4L following the formation of a dielectric in the plurality of openings.

FIG. 5B is an isometric illustration of the structure in FIG. 5A through the line A-A′.

FIG. 6A is cross sectional illustration of a cut mask implementation to form individual memory cells.

FIG. 6B is a plan view illustration of a portion of the mask over structure of FIG. 5A.

FIG. 7 is an isometric illustration of the structure in FIG. 5A post a cut etch process.

FIG. 8A is a cross sectional illustration of the structure in FIG. 7 through the line A-A′, following the process to form electrodes.

FIG. 8B illustrates the structure of FIG. 8A following the formation of a first set of conductors and a second set of conductors in the three levels of memory array.

FIG. 9 illustrates a computing device structure with a memory device structure arranged in accordance with at least some implementations of the present disclosure.

FIG. 10 is an illustrative diagram of a mobile computing platform employing a memory device structure arranged in accordance with at least some implementations of the present disclosure.

### DESCRIPTION OF THE EMBODIMENTS

Tier architecture for 3-D cross point memory and methods of fabrication are described. In the following description, numerous specific details are set forth, such as structural schemes and detailed fabrication methods in order to provide a thorough understanding of embodiments of the present disclosure. It will be apparent to one skilled in the art that embodiments of the present disclosure may be practiced without these specific details. In other instances, well-known features, such as operations associated with 3-D cross point memory, are described in lesser detail in order to not unnecessarily obscure embodiments of the present disclosure. Furthermore, it is to be understood that the various embodiments shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or material disposed over or under another may be directly in contact or may have one or more intervening materials. Moreover, one material disposed between two materials may be directly in contact with the two layers or may have one or more intervening layers. In contrast, a first material “on” a second material is in direct contact with that second material/material. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

As used throughout this description, and in the claims, a list of items joined by the term “at least one of” or “one or more of” can mean any combination of the listed terms.

Unless otherwise specified in the explicit context of their use, the terms “substantially equal,” “about equal” and “approximately equal” mean that there is no more than incidental variation between two things so described. In the art, such variation is typically no more than +/−10% of a predetermined target value.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

Memory cells are used in conjunction with large arrays of decoder transistors for a variety of 3-D cross point memory applications. A 3-D cross point memory array often includes a series of word lines on a first plane and series of bit lines on a second plane above the first plane, where the word lines orthogonally cross over the bit lines (or vice versa). A memory cell is located at each point of cross over (cross-point) between the word line and the bit line, where the memory cell couples a word line with a corresponding bit line to form a single memory array deck, or herein deck.

In embodiments, an effective cell size of a cross point memory cell is equal to a cell pitch squared divided by a number of decks. In some embodiments, a number of memory decks is approximately 6 or less. Memory scaling may be limited by a certain memory pitch (lateral spacing between memory cells) when an upper limit for the number of memory decks is reached. Memory density may be increased in conventional 3-D cross point memory by pitch scaling and stacking layers (increasing number of decks). However, production cost may increase significantly with more decks as a function of the number of process operations needed to fabricate each deck.

However, the inventors have devised an arrangement that can increase the number of stacks in a memory device structure without concomitantly increasing memory device production costs. In accordance with an embodiment of the present disclosure, the memory device structure includes memory cells where a memory element is laterally coupled with a selector element in each memory cell. In further embodiments, the memory device structure may include a plurality of memory cells in an array extending in two orthogonal directions on a plane to form a tier, or deck. The memory device structure may include a plurality of decks that are stacked. During operation, the memory device structure may permit the selection of a unique set of word line, bitline and tier/deck address to access a pair of memory cells.

The memory device structures described herein may advantageously reduce a number of decoder or programming transistors, providing a reduction in chip area. A decoder transistor may be individually coupled with each word line and a bit line to address a particular memory cell in a tier. When the number of memory cells are increased, the number of bit lines and word lines increase in proportion as does the number of decoder transistors required to address each memory cell (bit cell). To accommodate a larger number of decoder transistors in a vicinity of a cross point array, such as, for example below the cross-point memory array, relative lengths of a word line and bit line may be increased. Alternatively, decoder transistors may occupy a region laterally adjacent to the memory array. In either example a larger chip area may be utilized.

Increasing number of layers (tiers) of memory cells to form a 3-dimensional array can increase memory density per unit area. However, increasing the number of memory cells also proportionately increases the number of decoder transistors required. In some examples a single tier may include 4K bit lines and 4K word lines. Thus, a single 4K by 4K tier can require 8K decoder transistors. Because the number of decoder transistors increases proportionally with the number of tiers, enabling a high-density memory array for a given die size can be highly challenging.

In accordance with some embodiments, multiple (e.g., two) memory cells in a first cell block within one or more tiers are coupled through a first common electrode reduce the number of decoder transistors. Multiple (e.g., two) memory cells in a second adjacent cell block within the one or more tiers are also coupled through a second common electrode. To further reduce the number of decoder transistors, the first and the second common electrodes are coupled to single decoder transistor to provide simultaneous programming of multiple memory cells.

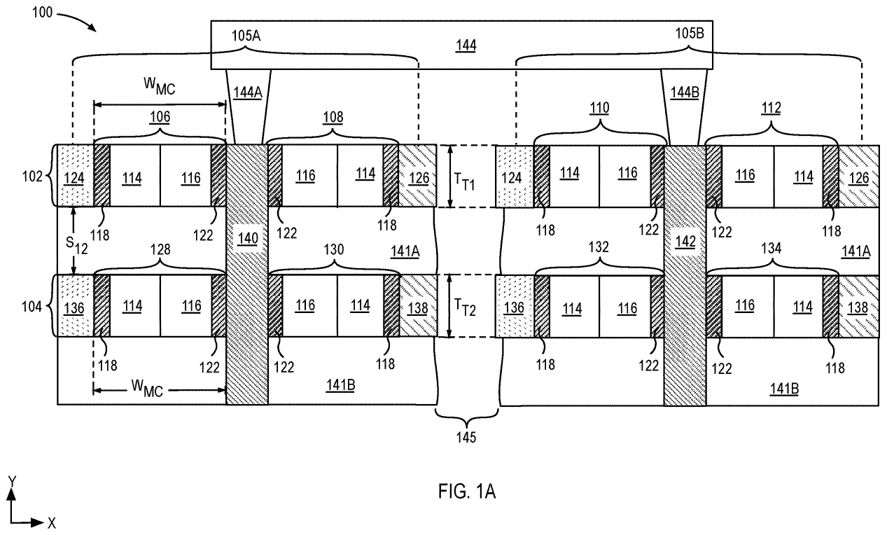

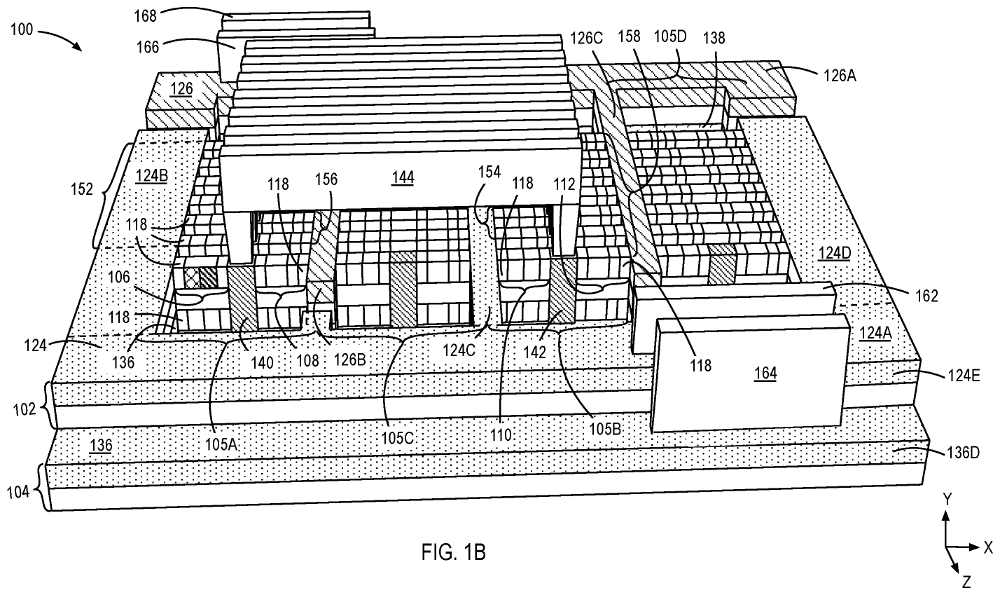

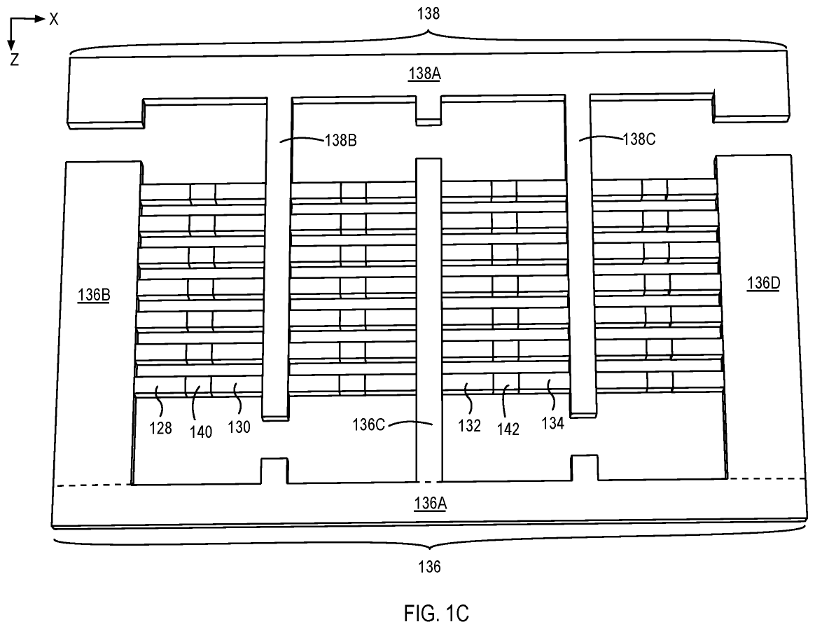

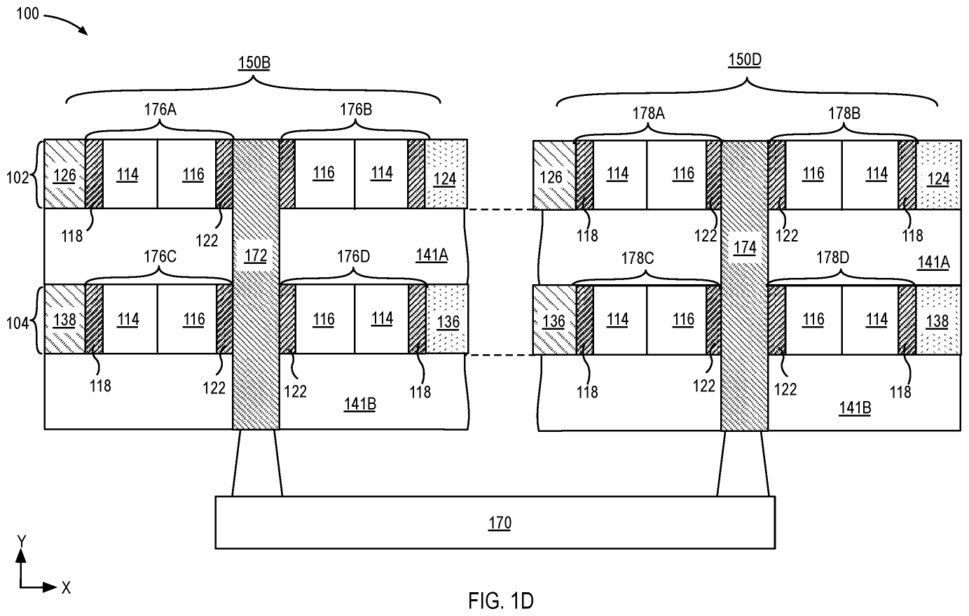

FIG. 1A is a cross illustration of a memory device structure 100 including a tiered memory array. Memory device structure 100 includes a pair of tiers, such as tier 102 and tier 104, where tier 102 is above tier 104. Memory device structure 100 further includes a plurality of cell blocks such as cell blocks 105A and 105B. In the illustrative embodiment, cell block 105A is spatially separate from cell block 105B, however one or more conductors within each of the respective cell blocks 105A and 105B may be electrically coupled. As shown, cell blocks 105A and 105B both include tiers 102 and 104.

In some embodiments, the conductor 124 is adjacent to the selector element 114 and conductor 140 is adjacent to the memory element as shown. In other embodiments, the conductor 124 is adjacent to the memory element and the selector element is adjacent to conductor 140. Tier 102 includes a plurality of memory cells, such as memory cells 106, 108, 110 and 112 along a first row. In the illustrative embodiment, each of the memory cells 106, 108, 110 and 110 includes a selector element 114 in series with a non-volatile memory element 116, between a terminal 118. In some embodiments, the selector element 114 is adjacent to terminal 118 and non-volatile memory element 116 is adjacent to terminal 122 such as is shown. In other embodiments, the selector element 114 is adjacent to terminal 122 and non-volatile memory element 116 is adjacent to terminal 118. Tier 102 includes a conductor 124 coupled with a respective terminal 118 of memory cell 106 and memory cell 110, and a conductor 126 coupled with respective terminals 118 of memory cell 108 and memory cell 112.

In the illustrative embodiment, tier 104 also includes a plurality of memory cells, such as memory cells 128, 130, 132 and 134 along a second row, where the second row is below and parallel to the first row. Each of the memory cells 128, 130, 132, and 134 includes a selector element 114 in series with a non-volatile memory element 116, between a terminal 118 and terminal 122. In some embodiments, the selector element 114 is adjacent to terminal 118 and non-volatile memory element 116 is adjacent to terminal 122 such as is shown. In other embodiments, the selector element 114 is adjacent to terminal 122 and non-volatile memory element 116 is adjacent to terminal 118. As shown, tier 104 further includes a conductor 136 coupled with respective terminals 118 of memory cell 128 and memory cell 132, and a conductor 138 coupled with respective terminals 122 of memory cell 130 and memory cell 134.

The memory cells are laterally (e.g., along x-axis) arranged to facilitate tier to tier spacing. In an embodiment, memory cells have a substantially equal lateral thickness across the various tiers. As shown, each of the memory cells 108, 110, 112, 128.130, 132, and 134 have a lateral thickness (along x-direction), W_{MC}. In embodiments, W_{MC}, is less than 125 nm. W_{MC} depends on eon characteristics of the memory element 116 and selector element 114, such as type of memory or selector element and number of layers within each element. In some exemplary embodiments, W_{MC}, is between 50 nm and 100 nm. In other embodiments, where memory cells include a built-in selector memory element, W_{MC}, can be between less than 40 nm. In some embodiments, the lateral width of each memory cell 106, 108, 110, 112 128, 130, 134 and 134 may vary between 2% and 10%.

To facilitate reduction of footprint of memory device structure 100, a plurality of memory cells across the tiers 102 and 104 may be coupled together. Structures that facilitate such coupling can help to increase memory density, while enabling each memory cell to be programmed independently.

A shown, cell block 105A includes a conductor 140 that advantageously provides electrical coupling between a plurality of memory cells. In the illustrative embodiment, conductor 140 is orthogonal to and extends between various tiers, such as between tiers 102 and 104. In the illustrative embodiment, the conductor 140 extends from tier 102 to tier 104 through a dielectric 141A. As shown, the conductor 140 is a via pillar (herein via pillar 140). The via pillar 140 couples a respective terminal 122 of memory cells 106 and 108 of tier 102 with a respective terminal 122 of memory cells 128 and 130 of tier 104. In the illustrative embodiment, via pillar 140 is adjacent to and between the respective terminals 122 of memory cell 106 and 108 and further adjacent to and between the respective terminals 122 of the memory cell 128 and 130. In the illustrative embodiment, the via pillar 140 extends into a dielectric 141B below memory cells 128 and 130.

A shown, cell block 105A includes a conductor 142 that advantageously provides electrical coupling between a plurality of memory cells. In the illustrative embodiment, conductor 142 is orthogonal to and extends between various tiers, such as between tiers 102 and 104. In the illustrative embodiment, the conductor 142 extends from tier 102 to tier 104 through a dielectric 141A. As shown, the conductor 140 is a via pillar (herein via pillar 142). The via pillar 140 couples a respective terminal 122 of memory cells 110 and 112 of tier 102 with a respective terminal 122 of memory cells 132 and 134 of tier 104. In the illustrative embodiment, via pillar 142 is adjacent to and between the respective terminals 122 of memory cells 110 and 112 and further adjacent to and between the respective terminals 122 of the memory cells 132 and 134. In the illustrative embodiment, the via pillar 142 extends into a dielectric 141B below memory cells 128 and 130. In exemplary embodiments, via pillars 140 and 142 can each be coupled to two memory cells per tier.

To increase the density of memory cells and facilitate fabrication, tiers 102 and 104 each have a respective vertical thickness, T_{T1}, and T_{T2}, that is between 20 nm and 30 nm. Tiers 102 and 104 are separated from each other by an insulator such as dielectric 141A. In embodiments, tier 102 is vertically separated from tier 104 by distance, S₁₂. In embodiments, S₁₂ is between 20 nm and 30 nm.

While via pillars 140 and 142 each facilitate programing of a single memory cell from a plurality of memory cells, to facilitate reduction in the number of decoder transistors in the memory device structure 100 a bridge conductor may be implemented. A bridge structure may be advantageously utilized to electrically couple two or more cells from different cell blocks. For example, when two memory cells are electrically coupled together by a bridge conductor, the total number of decoder transistors will be reduced by one-half. thus, saving chip real estate for other functional circuitry.

In the illustrative embodiment, a bridge conductor 144 is coupled to each of the via pillars 140 and 142 through a pair of interconnects. Depending on memory system needs, bridge conductor 144 can enable at least two memory cells to be programmed simultaneously. As shown, interconnect 144A is coupled between via pillar 140 and bridge conductor 144, and interconnect 144B is coupled between via pillar 142 and bridge conductor 144. As shown, bridge conductor extends laterally above cell block 105A and 105B. In the illustrative embodiment, bridge conductor 144 also extends laterally over a region 145 that include an adjacent cell block which has one or more features of cell block 105A or 105B. In embodiments, the bridge conductor 144 is coupled to a decoder transistor through a routing conductor (not shown).

In an embodiment, conductors 124 and 126 each include copper, tungsten, tantalum, titanium, hafnium, zirconium, aluminum, silver, tin, ruthenium, molybdenum, cobalt, and their alloys, or alloy including nitrogen and one or more of copper, tungsten, tantalum, titanium, hafnium, zirconium, aluminum, silver, titanium, tin or lead. In some embodiments, conductors 124 and 126 each include metal carbides such as hafnium carbide, zirconium carbide, titanium carbide, tantalum carbide or aluminum carbide.

In an embodiment via pillars 140 and 142 each include copper, tungsten, tantalum, titanium, hafnium, zirconium, aluminum, silver, tin, lead, ruthenium, molybdenum, cobalt, and their alloys, or alloy including nitrogen and one or more of copper, tungsten, tantalum, titanium, hafnium, zirconium, aluminum, silver, titanium, tin or lead. In some embodiments, via pillars 140 and 142 each include metal carbides such as hafnium carbide, zirconium carbide, titanium carbide, tantalum carbide or aluminum carbide.

In an embodiment, each of the bridge conductor 144, and interconnects 144A and 144B include copper, tungsten, tantalum, titanium, hafnium, zirconium, aluminum, silver, tin, lead, ruthenium, molybdenum, cobalt, and their alloys, or alloy including nitrogen and one or more of copper, tungsten, tantalum, titanium, hafnium, zirconium, aluminum, silver, titanium, tin or lead. In some embodiments, bridge conductor 144, and interconnects 144A and 144B each include metal carbides such as hafnium carbide, zirconium carbide, titanium carbide, tantalum carbide or aluminum carbide.

In an embodiment, terminals 118 and 122 include tungsten, tantalum, titanium, hafnium, zirconium, aluminum, silver, tin, lead, ruthenium, molybdenum, cobalt, and their alloys, or alloy including nitrogen and one or more of tungsten, tantalum, titanium, hafnium, zirconium, aluminum, silver, titanium, tin or lead. In some embodiments, terminals 118 and 122 each include metal carbides such as hafnium carbide, zirconium carbide, titanium carbide, tantalum carbide or aluminum carbide.

FIG. 1B is an isometric illustration of the memory device structure 100 in FIG. 1A. As shown conductors 124 and 126 have lateral extensions with interleaving line segments. Interleaving line segments can facilitate independent programming of at least a pair of memory cells in memory device structure 100. In the illustrative embodiment, conductors 124 and 126 are separated from each other by a distance to be sufficiently electrically isolated. In exemplary embodiments, 124 and 126 are separated from each other by at least 5 nm.

In the illustrative embodiment, conductor 124 includes a lateral portion 124A that has a longitudinal axis that is parallel to the first row of memory cells 106, 108 etc. As shown, conductor 124 further includes extensions 124B, 124C and 124D that are orthogonal to but in a plane (e.g., x-z plane) of the lateral portion 124A. As shown, extensions 124B and 124C are each coupled to a respective terminal 118 of each of the memory cells 106 and 110. Also shown in the illustration are a plurality of memory cells 152 that are staggered along the z-axis, and parallel to the memory cell 106 in cell block 105A. For example, extension 124B is coupled to a respective terminal 118 of each of the memory cells in the plurality of staggered memory cells 152. In the illustrative embodiment, extension 124B is coupled with 8 memory cells (including memory cell 106). Similarly, extension 124C is coupled with a plurality of staggered memory cells 154. In the illustrative embodiment, extension 124C is coupled with 8 memory cells (including memory cell 110).

As shown, conductor 126 includes a lateral portion 126A that has a longitudinal axis that is parallel to the first row of memory cells 106, 108 etc. As shown, conductor 126 further includes a plurality of extensions 126B, 126C that are orthogonal to but in the plane (x-z plane) of the lateral portion 126A. As shown, extensions 126B, 126C are each coupled to a respective terminal 118 of each of the memory cells 108 and 112. Also shown in the illustration are a plurality of memory cells 156 staggered along the z-axis parallel to the memory cell 108 in cell block 105A. For example, extension 126B is coupled to a respective terminal 118 of each of the memory cells in the plurality of staggered memory cells 156. In the illustrative embodiment, the lateral extension 126B is coupled with 8 memory cells (including memory cell 108). Similarly, extension portion 126C is coupled to a respective terminal 118 of each of the memory cells in the plurality of staggered memory cells 158. In the illustrative embodiment, the extension 126C is coupled with 8 memory cells (including memory cell 112). In the illustrative embodiment, the total number of memory cells in one tier of a cell block 105A or cell block 105C is 16. In other embodiments, the total number is greater than 16.

In exemplary embodiments, cell block 105B and 105D each include a plurality of memory cells that have one or more characteristics of the plurality of memory cells such as memory cells 106, 108, 110 and 112.

In an embodiment, each of the conductors 136 and 138 have a plan view shape that is substantially similar to a plan view shape of the conductor 124 and conductor 126, respectively. FIG. 1C is an isometric illustration of tier 104. Tier 102 is not shown for clarity. As shown, conductor 136 includes a lateral portion 136A that has a longitudinal axis that is parallel to memory cells 128, 130, 132 and 134. As shown, conductor 136 further includes a plurality of extensions 136B, 136C and 136D that are orthogonal to and in the plane (e.g., x-z plane) of the lateral portion 136A. As shown, conductor 138 includes a lateral portion 138A that has a longitudinal axis that is parallel to the second row of memory cells 128, 130 etc. As shown, conductor 138 further includes a plurality of extensions 138B and 138C that are orthogonal to but in the plane (e.g., x-z plane) of the. lateral portion 138A.

Referring again to FIG. 1B, a larger footprint of conductors 136 and 138 relative to conductors 124 and 126, respectively, facilitates positioning of terminal contacts, as shown. In the illustrative embodiment, a terminal contact 162 couples an interconnect line (not shown) with the conductor 124, and terminal contact 164 couples an interconnect line (not shown) with the conductor 136, terminal contact 166 couples an interconnect line (not shown) with the conductor 126 and a terminal contact 168 couples an interconnect line (not shown) with the conductor 138.

In one or more embodiments, the interconnects (not shown) extend laterally, parallel to the lateral extension 124A. A larger footprint of conductors 136 and 138 relative to conductors 124 and 126, respectively, facilitates positioning of terminal contacts shown. In an exemplary embodiment, conductor 136 extends laterally beyond conductor 124. As shown a sidewall 136D of the conductor 136 laterally extends beyond a sidewall 124E of the conductor 124 (indicated by dashed lines). Sidewall of conductor 138 also laterally extends beyond a sidewall of conductor 126 (hidden in the illustration).

While two tiers have been illustrated in FIGS. 1A and 1B, in some embodiments, memory device structure 100 includes up to 9 tiers. The plurality of staggered memory cells along the z-direction in each of the tiers 102 and 104 constitutes a 3-dimensional array of memory cells.

FIG. 1D is a cross sectional illustration through the line A-A′ in FIG. 1B. The cell blocks 105B and 105D are coupled under tier 104 by a bridge conductor 170 below the cell blocks 105B and 105D. In the illustrative embodiment, bridge conductor 170 is coupled with via pillar 172 of cell block 105B and via pillar 174 of cell block 105D.

In an embodiment, cell block 105B has a plurality of memory cells 176A, 176B, 176C and 176D that have one or more characteristics of the memory cells 106, 108, 128 and 130, respectively. In an embodiment, cell block 105D has a plurality of memory cells 178A, 178B, 178C and 178D that have one or more characteristics of the memory cells 110, 112, 132 and 134, respectively.

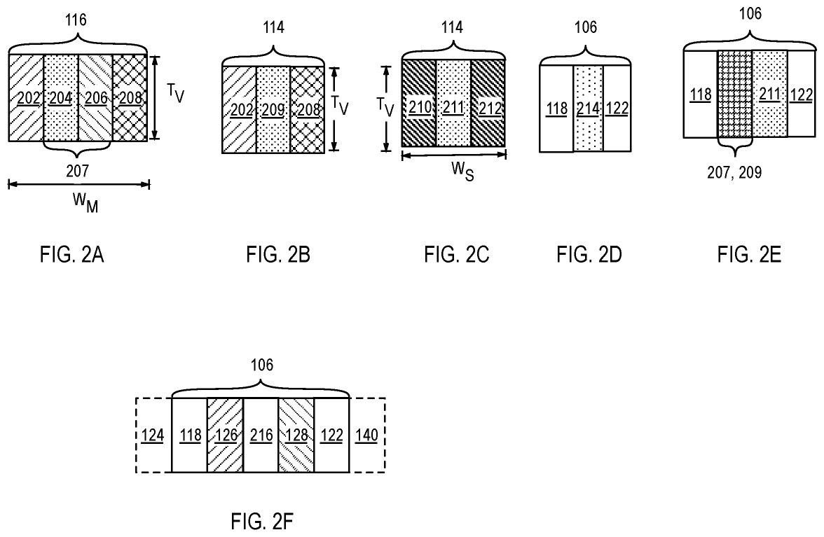

FIG. 2A is a cross-sectional illustration of a memory element. In some embodiments all memory cells within a given tier 102 or 104 have the same configuration. The memory element 116 may include phase change memory, a resistive random access memory (R-RAM), ovonic threshold switching (OTS) memory or a conductive bridge RAM. In an exemplary embodiment, the layers within the memory element are laterally adjacent to each other and are indicative of a processing operation utilized.

In one embodiment, the memory element 116 is a resistive random-access memory (RRAM) device. In the illustrated embodiment, the memory element 116 includes an electrode 202, a switching layer 204 adjacent to the electrode 202, an oxygen exchange layer 206 adjacent to the switching layer 204, and an electrode 208 adjacent to the oxygen exchange layer 206. The switching layer 204 and oxygen exchange layer 206 may be collectively referred to as a storage layer 207.

In an embodiment, electrode 202 includes an amorphous layer. In an embodiment, electrode 202 is a topographically smooth electrode. In an embodiment, electrode 202 includes a material such as W, Ta, Mo, Ru, Co TaN or TiN. In an embodiment, electrode 202 has a lateral thickness is between 1 nm and 10 nm. In an embodiment, electrode 208 includes a material such as W, Ta, Mo, Ru, Co TaN or TiN. In an embodiment, electrode 208 has a lateral thickness is between 1 nm and 10 nm. In an embodiment, electrode 202 and electrode 208 include a same material to facilitate symmetric RRAM switching characteristics. In an embodiment, electrodes 202 and 208 each include a same metal such as Ta or TiN.

Switching layer 204 may be a metal oxide, for example, including oxygen and atoms of one or more metals, such as, but not limited to Hf, Zr, Ti, Ta or W. In the case of titanium or hafnium, or tantalum with an oxidation state +4, switching layer 204 has a chemical composition, MO_{X}, where O is oxygen and X is or is substantially close to 2. In the case of tantalum with an oxidation state +5, switching layer 204 has a chemical composition, M₂O_{X}, where O is oxygen and X is or is substantially close to 5. In an embodiment, switching layer 204 has a thickness is between 1 nm and 5 nm.

Oxygen exchange layer 206 acts as a source of oxygen vacancy or as a sink for O²⁻. In an embodiment, oxygen exchange layer 206 is composed of a metal such as but not limited to, hafnium, tantalum or titanium. In an embodiment, oxygen exchange layer 206 has a thickness is between 5 nm and 20 nm. In an embodiment, the thickness of oxygen exchange layer 206 is at least twice the thickness of switching layer 204. In another embodiment, the thickness of oxygen exchange layer 206 is at least twice the thickness of switching layer 204. The combined lateral thickness of storage layer 207 may be between 3 nm and 15 nm. In an embodiment, the memory element 116 has lateral thickness, WM, that is between 7 nm and 35 nm. In an embodiment, the memory element 116 has a vertical thickness, T_{V}, that is between 5 nm and 35 nm. In embodiments where the electrode 202 includes a material that is the same as the material of the terminal 118 or 122 (not shown), then memory element does not include a separate electrode 202. In some such embodiments, where memory element 116 is directly adjacent to an insulator of selector element 114 (not shown), memory element 116 has a lateral width, WM, that is between 3 nm and 15 nm.

In other embodiments, the non-volatile memory element 116 includes only electrodes 202 and 208 and an insulator 209 in between, as shown in FIG. 2B. In some such embodiments, the insulator layer 209 exhibits charge carrier tunneling behavior. In some such embodiments, the insulator layer 209 includes oxygen and a metal, such as, but not limited, to aluminum, hafnium, tantalum and titanium. In further embodiments, the insulator layer 209 is also doped with atoms of one or more metals, such as, but not limit to, copper, silver or gold. In some such embodiments, the insulator layer 209 is doped to a concentration between 2%-10% (atomic) with atoms of one or more metals such as copper, silver or gold. In an embodiment, the insulator layer 209 has a thickness between 2 nm to 5 nm.

In another embodiment, the insulator layer 209 includes a threshold switching material such as a phase change material. In some examples, the insulator layer 209 may include a phase change material that exhibits at least two different electrical states characterized by two different resistances, a conductive state and a resistive state. In some examples, the phase change material exhibits at least two different material states, amorphous and crystalline that correspond to the two different resistance states. In an embodiment, a phase change material that is in a completely crystalline phase is conductive and resistive when the phase change material is in an amorphous state. However, by modulating the relative extent of crystalline phase and amorphous phase in a given volume of the phase change material the resistance of the phase change material can be tuned. In an embodiment, the resistance state of the phase change material may be set by heating and cooling the phase change material in a specific manner by application of a voltage bias, e.g., between electrodes 202 and 208 to induce joule heating.

In an embodiment, the phase change material includes Ge and Te. In an embodiment, the phase change material further includes Sb. In an embodiment, the phase change material includes a ternary alloy of Ge, Te and Sb such as Ge₂Sb₂Te₅. In an embodiment, the phase change material includes a binary alloy, ternary alloy or a quaternary alloy including at least one element from the group V periodic table such as Te, Se, or S. In an embodiment, the phase change material includes a binary alloy, ternary alloy or a quaternary alloy which comprises at least one of Te, Se, or S, where the said alloy further comprises one element from the group V periodic table such as Sb. In an embodiment, the phase change material includes a dopant such as silver, indium, gallium, nitrogen, silicon or germanium. In an embodiment, the dopant concentration is between 5% and 20% of the total composition of the phase change material. In an embodiment, the insulator layer 209 has a thickness (measured along e.g., x-axis) that is between 2 nm and 15 nm.

FIG. 2C is a cross-sectional illustration of a structure of a selector element 114, in accordance with an embodiment of the present disclosure. As shown the selector device includes a metal-insulator-metal (MIM) stack. The MIM stack of selector element 114 includes a selector electrode 210, and an insulator layer 211 between the selector electrode 210 and a selector electrode 212. In embodiments, the insulator layer 211 includes a ovonic threshold switching material. In an embodiment, the insulator includes alloy of Ge, As and Se, such as GeAsSe, GeSe or AsSe. In embodiments the alloy Ge, As and Se may include dopants, for example As doped GeSe, Ge doped AsSe or GeAsSe doped with In, Te or Sb. In embodiments, the insulator layer 211 has a thickness that is material dependent, where the thickness is between 5 nm and 30 nm. Electrodes 210 and 212 may include a material that is the same or substantially the same as a material of electrodes 202 and 208.

In another embodiment, the insulator layer 211 includes a material that can undergo a reversible insulator to metal transition. In an embodiment, the transition is triggered by a thermal process. In another embodiment, the transition is triggered by an electrical process. The insulator to metal transition is characterized by a high resistance insulator state and a low resistance metallic state. In some such embodiments, the insulator layer transition comprises the development of filamentary conduction in which a filament may extend through the insulator to couple the selector electrodes 210 and 212. The extent of such a filament may modulate during the transition between the insulator and metallic states as a function of voltage developed across selector electrodes 210 and 212. In some such embodiments, the insulator layer 211 includes oxygen and atoms of one or more metals, such as, but not limited to niobium, vanadium and tantalum. In some specific examples, the insulator layer 211 includes vanadium (IV) oxide, VO₂ and vanadium (V) oxide, V₂O₅ and niobium (V) oxide, Nb₂O₅. In one specific example, the insulator layer 211 includes niobium (V) oxide, Nb₂O₅ and may exhibit filamentary conduction. When the insulator layer 211 includes a material exhibiting filamentary conduction, a filament may manifest within the insulator layer 211. In an embodiment, the insulator layer 211 is amorphous. In an embodiment, the insulator layer 211 which can undergo an insulator to metal transition has a thickness between 20 nm and 50 nm.

In some embodiments where insulator-to-metal transition is to occur, the insulator layer 211 further includes a dopant such as silver, copper or gold. In an embodiment, the dopant concentration is between 0.1-10% of the total composition of the insulator layer 211. A dopant concentration between 0.1-10% may facilitate filament conduction. In an embodiment, the insulator layer 211 has a thickness between 5 nm and 15 nm. In an embodiment, the selector electrode 210 includes a conductive material such as TiN and TaN or a metal such as Ta, W or Pt. In an embodiment, the selector electrode 210 has a thickness between 2 nm and 10 nm. In an embodiment, the selector electrode 212 includes a conductive material such as TiN and TaN or a metal such as Ta, W or Pt. In an embodiment, the selector electrode 212 has a lateral thickness between 2 nm and 25 nm. In embodiments, selector element 114 has a vertical thickness, T_{V}, that is between 5 nm and 35 nm.

FIG. 2D is a cross-sectional illustration of a memory cell 106 that includes terminals 118 and 122 and an insulator layer 214 between terminals 118 and 122 that includes characteristics of a selector and a memory cell. In some such embodiments, insulator layer 214 includes an ovonic threshold switching material such as layer 211 that may function as a built-in-selector memory. In embodiments, the insulator layer 214 can exhibit selector or memory behavior that is dependent on a polarity and magnitude of an applied voltage pulse between the terminal 118 and terminal 122. In one embodiment, the insulator exhibits an RRAM like behavior where the applied voltage induces a resistance change in the insulator layer 214. The application of the electrical pulse drives dopants in the insulator layer 214 towards terminal 118 or 122 and changes the electrochemical potential of the insulator layer 214 reflecting in a resistance change. In other embodiments, application of a one-time voltage pulse (OTP) causes an electrical breakdown and allowing conduction in the insulator layer 214, a behavior resembling a selector.

In some such embodiments, insulator layer 209 or storage layer 207 of a memory element is directly adjacent to insulator layer 211 of a selector element as shown in FIG. 2E. In some such embodiments, there is no electrode between insulator layer 209 or storage layer 207 and insulator layer 211. In some such embodiments, each of the terminals 118 and 122 may also function as electrodes for the memory cell 106.

In some embodiments, memory cell 106 includes a terminal 216 between the memory element 116 and selector element 114 such as is shown in the cross-sectional illustration of FIG. 2F. In some embodiments, the material of the terminal 216 is sufficiently suitable for an electrode for both the memory element 116 and selector element 114. Terminal 216 may include a material that is the same or substantially the same as the material of the terminal 118 or 122. Terminal 216 may have a lateral thickness that is between 1 nm and 5 nm.

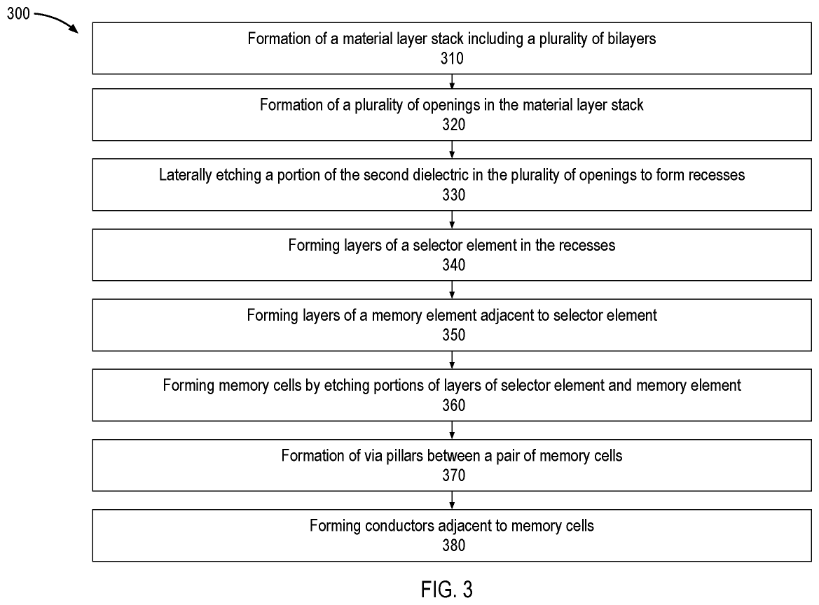

FIG. 3 is a method 300 to fabricate a memory cell array described in association with FIGS. 1A-1D, in accordance with an embodiment of the present disclosure. The method 300 begins at operation 310 with the formation of a material layer stack including a plurality of bilayers of a first dielectric above a second dielectric above a substrate. The method 300 continues at operation 320 with the formation of a plurality of openings in the material layer stack. The method 300 continues at operation 330 to laterally recess a portion of the second dielectric in the plurality of openings. The method 300 continues at operation 340 with the process of deposition and etching layers of a selector element. The method 300 continues at operation 350 with the process of deposition and etching layers of a memory element. The method 300 continues at operation 360 with the process of isolating a plurality of memory cells. The method 300 continues at operation 370 with the formation of a via pillars between each pair of memory cells. The method 300 concludes at operation 380 with replacing the first dielectric with an electrode material.

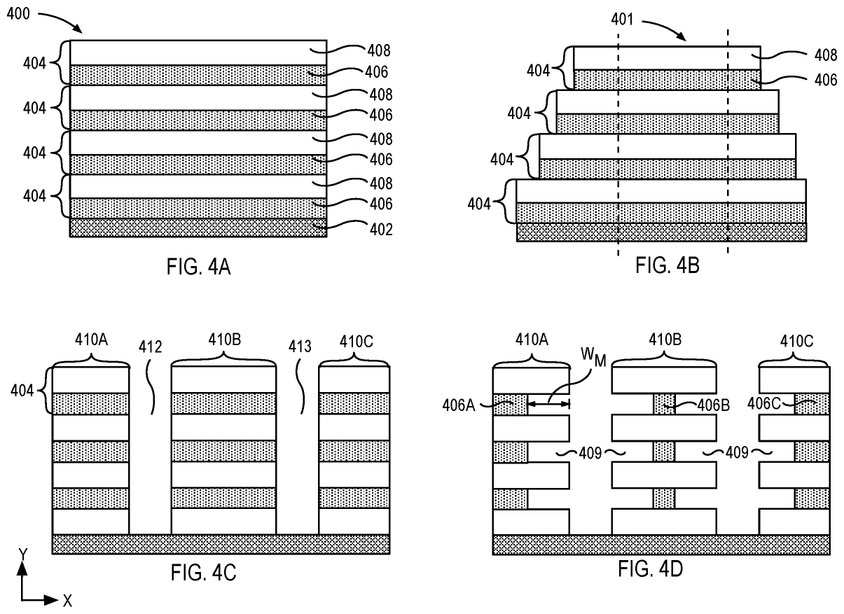

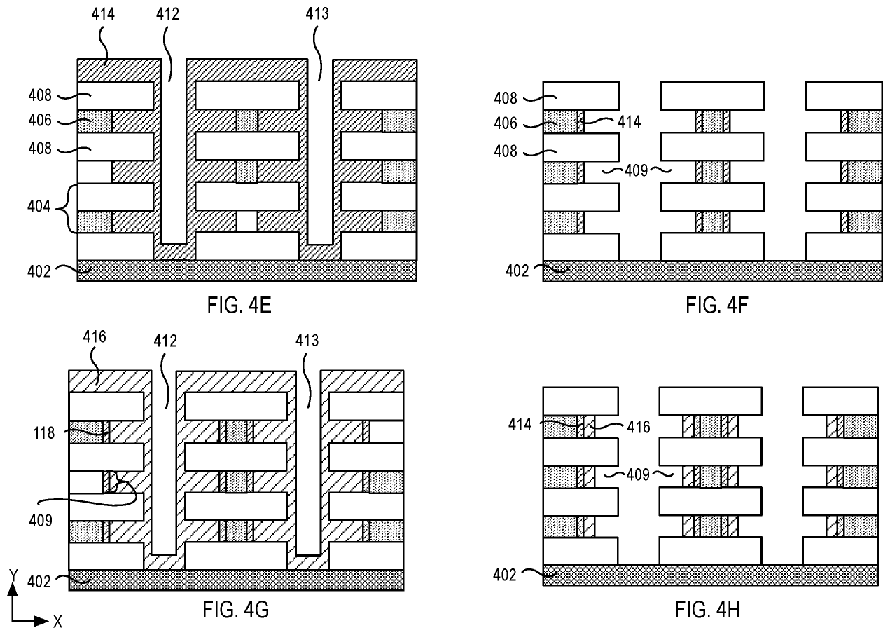

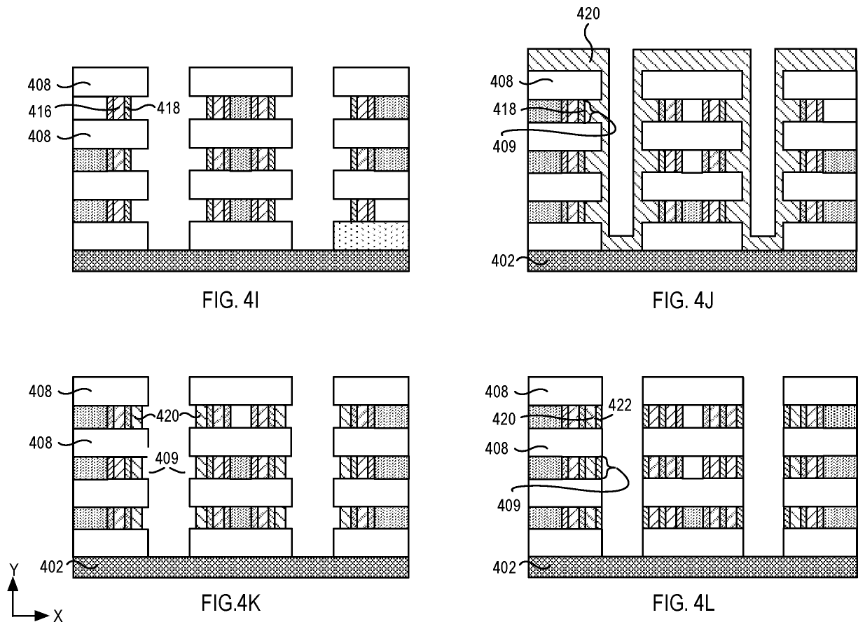

FIG. 4A illustrates a material layer stack 400 formed above a dielectric 402. In the illustrative embodiment, forming the material layer stack 400 includes forming a plurality of bilayers 404, where each bilayer 404 includes a dielectric layer 406 and a dielectric layer 408 on dielectric layer 406. In an embodiment, the dielectric layer 406 is blanket deposited by a (PECVD) or a chemical vapor deposition (CVD) process. In an embodiment, the dielectric layer 406 includes silicon and at least one of nitrogen, or carbon, for example, silicon nitride, or silicon carbide. The dielectric layer 406 in a lowest bilayer acts an etch stop during formation of pillar vias. The deposition process continues with deposition of a dielectric layer 408 on the dielectric layer 406. In an embodiment, the dielectric layer 408 includes silicon, and oxygen. In other embodiments, the dielectric layer 408 includes silicon, and oxygen and at least one of nitrogen, or carbon. The material of the dielectric layer 406 is different from the material of dielectric layer 408, where either dielectric layer 406 or dielectric layer 408 can be removed or etched selectively to the other. The dielectric layer 408 may be blanket deposited by a (PECVD) or a chemical vapor deposition (CVD) process to a thickness between 20 nm and 40 nm. The thickness of dielectric layer 408 determines a maximum thickness of a memory cell that can be formed. The deposition process continues with a formation of a plurality of bilayers 404.

In an embodiment, dielectric 402 includes silicon and one or more of oxygen, nitrogen or carbon, such as silicon oxide, silicon-oxynitride, silicon nitride, silicon oxy-carbide or silicon carbide.

FIG. 4B is a cross-sectional illustration of the structure in FIG. 4A following the process to mask and etch to form a staircase structure. In an embodiment, a plasma etch process is utilized to mask and etch dielectric layer 406 and 408 in the individual bilayers. The fabrication process is continued with a process to repeat masking and etching until the staircase structure 401 is formed.

FIG. 4C is a cross-sectional illustration of a material layer stack portion 410 of the stair case structure 401 in FIG. 4B, following the process to etch and form plurality of openings 412 and 413. In an embodiment, a plasma etch process is utilized to etch the plurality of bilayers 404. In an embodiment, the opening 412 and 413 has substantially vertical sidewall profiles relative to an uppermost surface of the dielectric 402.

FIG. 4D illustrates the structure of FIG. 4C following a process to laterally recess portions of the dielectric 406, selectively to the dielectric 408 and 402 to form a plurality of recesses 409. In an embodiment, the lateral recess may be formed by an atomic layer etching process, a plasma etch process, a wet chemical process or a combination thereof.

In an embodiment, the lateral recess in the dielectric 406 in material layer stack portions 410A, 410B and 410C has a substantially similar width. In an embodiment, the lateral recess has a width, WM, that is chosen to accommodate formation of a memory cell, such as memory cell 106 Additionally, in the cross-sectional illustration dielectric 406 has three portions 406A, 406B and 406C in each bilayer 404. For example, portion 406A is within material layer stack portion 410A, portion 406B is within material layer stack portion 410B, and portion 406B is within material layer stack portion 410C. In an embodiment, material layer stack portion 410A and 410C have a width that are chosen to accommodate formation of one memory cell, and material layer stack portion 410B has a width that is chosen to accommodate the formation of two memory cells adjacent to dielectric 406.

The dielectric 406 is a material that will be substituted for a conductor material of a tier, such as conductor 124 or 126 in a downstream operation. Dielectric 406 has a vertical thickness that is representative of at thickness of a tier such as tier 102 or 104.

FIG. 4E illustrates the structure of FIG. 4D following the formation of an electrode material 414 in the openings 412 and 413 in the plurality of lateral recesses adjacent to dielectric 406. In an embodiment, the electrode material 414 is also deposited on the dielectric 402. In an embodiment, the electrode material includes a material that is the same or substantially the same as the material of the conductor 124.

FIG. 4F illustrates the structure of FIG. 4E following the process to etch and remove portions of the electrode material 414 from the openings 412 and 413 and from portions of lateral recesses 409 adjacent to dielectric 406. A portion of electrode material 414 remains adjacent to the dielectric 406 between two alternating dielectric layers 408. In an embodiment, the electrode material 414 is removed by an atomic layer etch, a plasma etch process, a wet etch process or a combination thereof. In the illustrative embodiment, the electrode material 414 is also removed from surface of dielectric 402.

FIG. 4G illustrates the structure of FIG. 4F following the deposition of a selector material 416 in the plurality of recesses 409 adjacent to the electrode material 414. The selector material 416 is also deposited adjacent to dielectric 408. One or more layers of the selector material 416 may be deposited by an atomic layer deposition process. In an embodiment, the selector material 416 is also deposited on the dielectric 402.

FIG. 4H illustrates the structure of FIG. 4G following the process to etch and remove portions of the selector material 416 from portions of lateral recesses 409 adjacent to electrode material 414. A portion of selector material 416 remains adjacent to the electrode material 414 between two alternating dielectric layers 408. In an embodiment, the selector material 416 is removed by an atomic layer etch, a plasma etch process, a wet etch process or a combination thereof. In the illustrative embodiment, portions of the selector material 416 are also removed from surface of dielectric 402.

FIG. 4I illustrates the structure of FIG. 4H following the formation of electrode material 418 adjacent to selector material 416. In an embodiment, the process to form electrode material 418 is the same or substantially the same as the process to form electrode material 414. Electrode material 418 may be deposited in openings 412 and 413 and within the plurality of recesses 409 adjacent to the selector material 416 by an atomic layer deposition process. Portions of the electrode material 418 may be etched and removed, such as from above dielectric 402 and from sidewall portions of dielectric 408 as well as from portions of the plurality of recesses 409.

FIG. 4J illustrates the structure of FIG. 4I following the deposition of one or more layers of memory material 420 in openings 412 and 413 and within the plurality of recesses 409 adjacent to electrode material 418. The memory material 420 is also deposited adjacent to selector material 416 and on the dielectric 402. In an embodiment, one or more layers of memory material 420 is deposited are deposited by an atomic layer deposition process to fill the plurality of recesses 409.

FIG. 4K illustrates the structure of FIG. 4J following the process to etch and remove portions of the memory material 420 and from portions of lateral recesses 409 adjacent to electrode material 418 and from between two alternating dielectric layers 408. In an embodiment, portions of the memory material 420 are removed by an atomic layer etch, a plasma etch process, a wet etch process or a combination thereof. In the illustrative embodiment, the memory material is also removed from surface of dielectric 402.

FIG. 4L illustrates the structure of FIG. 4K following the formation of electrode material 422 adjacent to the memory material 420, between any two alternating dielectric layers 408.

In an embodiment, the process to deposit and remove portions of electrode material 422 is the same or substantially the same as the process utilized to deposit and remove portions of electrode material 414. In an embodiment, electrode material 422 is deposited into the plurality of recesses 409 adjacent to the memory material 420 between two alternating dielectric layers 408. Portions of the electrode material 422 are etched and removed as described above, such as from above dielectric 402 and from portions of the plurality of recesses 409.

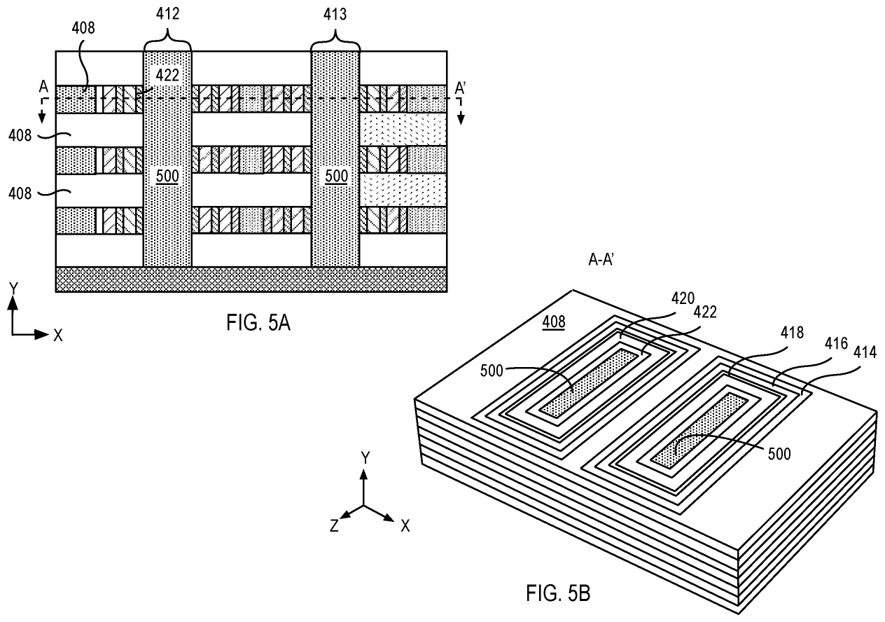

FIG. 5A illustrates the structure of FIG. 4L following the formation of a dielectric 500 in the openings 412 and 413. In an embodiment, the dielectric 500 is deposited in the openings 412 and 413, on the dielectric 402 and adjacent to dielectric 408, electrode material 422. The dielectric 500 may include silicon and one or more of oxygen, nitrogen or carbon. However, the dielectric 500 includes a material that can be etched selectively to dielectric 402, 406 and 408 in a subsequent downstream operation.

FIG. 5B is an isometric illustration of the structure in FIG. 5A through the line A-A′. As shown dielectric 500 is laterally surrounded by electrode material 422. In the illustrative embodiment, the electrode material 422 is laterally surrounded by memory material 420, memory material 420 is laterally surrounded by electrode material 418, electrode material 418 is laterally surrounded by selector material 416, and selector material 416 is laterally surrounded by electrode material 414. In the illustrative embodiment, the formation of two ringed structures can enable formation of 4 memory cells.

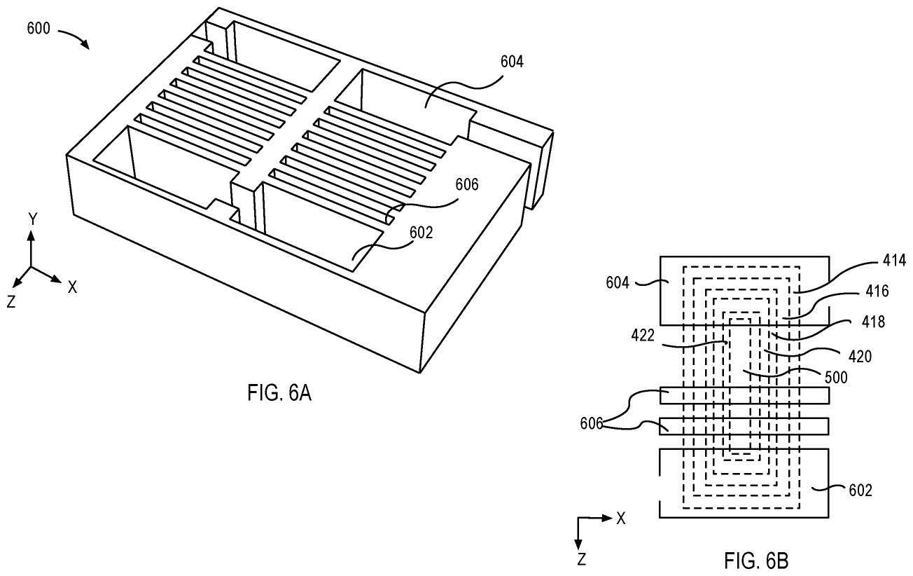

FIG. 6A is cross sectional illustration of a cut mask implementation to form individual memory cells. In the illustrative embodiment, mask 600 is formed on the structure of FIG. 5A. Mask 600 has features such as a plurality of openings 602, 604. In the illustrative embodiment, openings 602 and 604 are utilized to remove end caps and the plurality of openings 606 will be utilized to form memory cells.

FIG. 6B is a plan view illustration of a portion of the mask over structure of FIG. 5A. In the illustrative embodiment, the openings 602 and 604 are utilized to form isolated memory cells. An outline of the electrode material 422, memory material 420, electrode material 418, selector material and electrode material 414 is shown via dashed lines to illustrate regions that will be removed by portions of the mask 600.

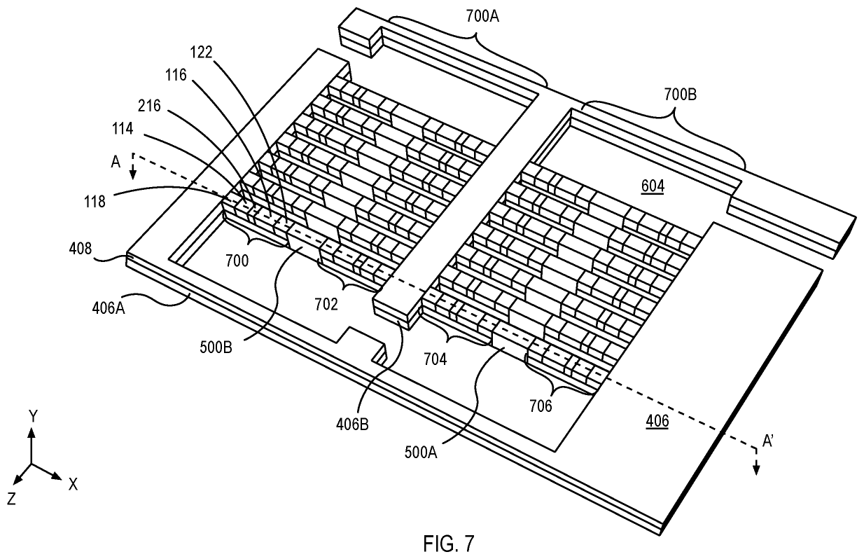

FIG. 7 is an isometric illustration of the structure in FIG. 5A post a cut etch process. In the illustrative embodiment, the cut etch process etches portions of dielectric 408 and 406, dielectric 500, electrode material 422, memory material 420, electrode material 418 and selector material 416. In the illustrative embodiment, the process of etching forms cell blocks 700A and 700B. A single tier is shown in the isometric illustration.

Etching also forms a plurality of discrete dielectric blocks, such as dielectric blocks 500A and 500B. The etching process also forms memory cells 700, 702, 704 and 706. In some embodiments, memory cells 700, 702, 704 and 706 have one or more features of the memory cell 106 described in association with FIG. 2F.

The memory cells in the illustrative embodiment have a rectangular prism shape. As shown, memory cells have sidewall surfaces that are substantially vertical. In other embodiments sidewalls may be tapered. In some embodiments, the cut etch process forms sidewalls of memory cells 700, 702,704 and 706 are substantially co-planar with sidewalls of the dielectric portions 500A and 500B. In other embodiments, sidewalls of memory cells 700, 702,704 and 706 are not co-planar with sidewalls of the dielectric portions 500A and 500B.

As shown, dielectric blocks 500A and 500B are formed between memory cells 700 and 702, and between 704 and 706 respectively. Also as shown, the process of etching forms terminal 118, terminal 122, terminal 216, selector element 114 and memory element 126 in each memory cell. In an exemplary embodiment, there are 16 memory cells in each cell block. The number of desired memory cells may be chosen by a design of the mask 600 (not shown). It is to be appreciated that the dielectric 406 is separated into two portions dielectric portion 406A and dielectric portion 406B after the cut etch process.

In other embodiments, the process described above may be modified to alter the composition of the memory element or selector element in memory cell 700. In other embodiments, electrode 216 may not be formed. In some such embodiments, memory cells 700, 702, 704 and 706 have one or more features of the memory cell 106, 108 etc described in association with FIG. 1A. In general, memory cells 700, 702, 704 and 706 have one or more features of the memory cell described in association with FIG. 2E.

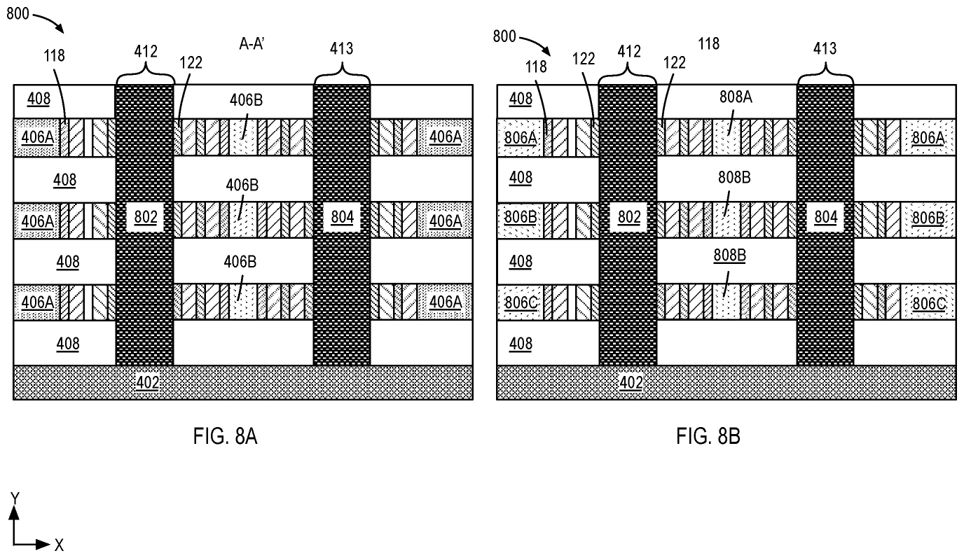

FIG. 8A is a cross sectional illustration of the structure in FIG. 7 through the line A-A′, following the process to form conductors 802 and 804. In the illustrative embodiment, three layers or tiers of vertically arranged memory cells are shown. In other embodiments, the number of tiers can be up to 8.

In an embodiment, dielectric blocks 500A and 500B are removed. In an embodiment, a plasma etch, a wet etch or a combination thereof may be utilized to remove dielectric blocks 500A and 500B to re-form openings 412 and 413. In an embodiment, an electrode material is deposited in the openings 412 and 413, adjacent to terminal 122 of each memory cell, and on dielectric 402. The electrode material may be polished after deposition to form a multi-tiered memory array 800.

FIG. 8B illustrates the structure of FIG. 8A following the formation of conductors 806A, 806B and 806C, and conductors 808A, 808B and 808C in the three levels of memory array. In an embodiment, the dielectric 406A is removed from the structure of FIG. 8A. In an embodiment, a wet chemical process is utilized to remove the dielectric 406A adjacent to dielectric 408 and terminal 118 and form openings between alternative layers of dielectric 408. An electrode material is then deposited to fill into the openings formed by removal of the dielectric 406A.

After conductors 806A, 806B and 806C are formed, a second mask may be utilized to selectively remove dielectric 406B from the structure of FIG. 8A. Referring again to FIG. 8B, In an embodiment, a wet chemical process is utilized to remove the dielectric 406B adjacent to dielectric 408 and terminal 122 and form openings between alternative layers of dielectric 408. An electrode material is then deposited to fill into the openings formed by removal of the dielectric 406B. Dielectric 406B may be removed concurrently with dielectric 406A.

In an embodiment, dielectric portions 406A and 406B may be removed at the same time and a same electrode material may be utilized to form conductors 806A, 806B and 806C and conductors 808A, 808B and 808C. However, a second cut mask may be required to etch the electrode material to isolate 808A, 808B and 808C from 806A, 806B and 806C.

While not shown, a conductive bridge (for example conductive bridge 144 described in association with FIG. 1A) may be formed on conductors 802 and 804 to render a structure similar to the memory device structure 100 described in association with FIGS. 1A-1C.

In other embodiments, a conductive bridge such as conductive bridge 170 (illustrated in FIG. 1D) may be formed in the dielectric 402, prior to patterning the material layer stack 400 illustrated in FIG. 4A.

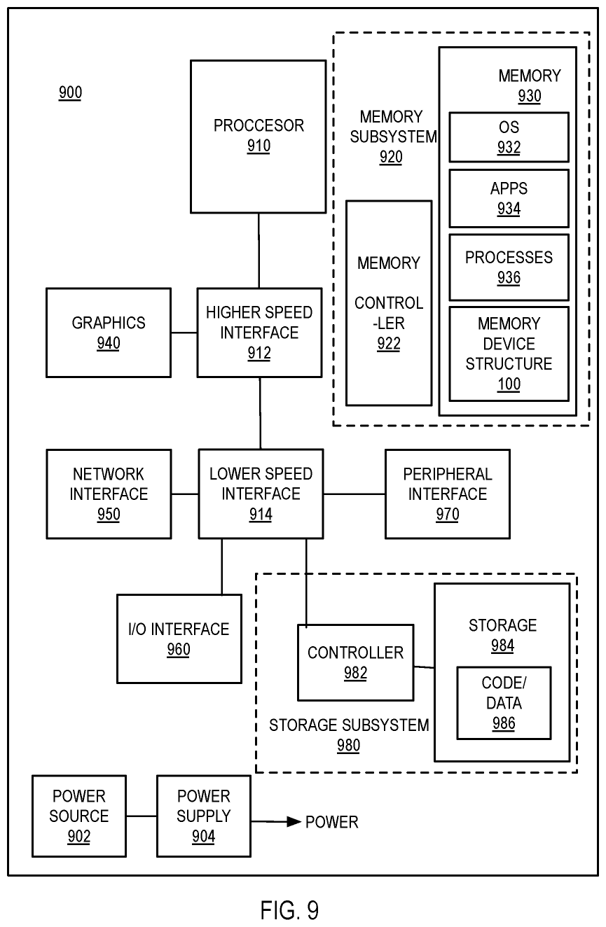

FIG. 9 is a block diagram of an example of a computing system in which a memory device structure can be implemented. System 900 represents a computing device in accordance with any example herein, and can be a laptop computer, a desktop computer, a tablet computer, a server, a gaming or entertainment control system, embedded computing device, or other electronic device.

System 900 includes a memory device structure in memory 930, such as for example memory device structure 100 described in association with FIG. 1A. The memory structure 100 enables memory 930 to provide selection of a target cell within the memory array. The use of the described memory structure 100 enables selection with lower energy usage as compared to traditional decoder transistors due to a reduced number of decoder transistors utilized.

System 900 includes processor 910 can include any type of microprocessor, central processing unit (CPU), graphics processing unit (GPU), processing core, or other processing hardware, or a combination, to provide processing or execution of instructions for system 900. Processor 910 controls the overall operation of system 900, and can be or include, one or more programmable general-purpose or special-purpose microprocessors, digital signal processors (DSPs), programmable controllers, application specific integrated circuits (ASICs), programmable logic devices (PLDs), or a combination of such devices.

In one example, system 900 includes interface 912 coupled to processor 910, which can represent a higher speed interface or a high throughput interface for system components that need higher bandwidth connections, such as memory subsystem 920 or graphics interface components 940. Interface 912 represents an interface circuit, which can be a standalone component or integrated onto a processor die. Interface 912 can be integrated as a circuit onto the processor die or integrated as a component on a system on a chip. Where present, graphics interface 940 interfaces to graphics components for providing a visual display to a user of system 900. Graphics interface 940 can be a standalone component or integrated onto the processor die or system on a chip. In one example, graphics interface 940 can drive a high definition (HD) display that provides an output to a user. In one example, the display can include a touchscreen display. In one example, graphics interface 940 generates a display based on data stored in memory 930 or based on operations executed by processor 910 or both.

Memory subsystem 920 represents the main memory of system 900 and provides storage for code to be executed by processor 910, or data values to be used in executing a routine. Memory subsystem 920 can include one or more memory devices 930 such as read-only memory (ROM), flash memory, one or more varieties of random access memory (RAM) such as DRAM or other memory devices, or a combination of such devices. In some embodiments memory subsystem 920 includes persistent memory (PMem) which may offer higher RAM capacity than traditional DRAM. PMem may operate in a persistent mode storing data without power applied to the memory subsystem 920 for non-volatile data storage. In other embodiments, memory subsystem 920 includes solid state drives (SSDs), residing in a NAND package for fast storage.

Memory 930 stores and hosts, among other things, operating system (OS) 932 to provide a software platform for execution of instructions in system 900. Additionally, applications 934 can execute on the software platform of OS 932 from memory 930.

Applications 934 represent programs that have their own operational logic to perform execution of one or more functions. Processes 936 represent agents or routines that provide auxiliary functions to OS 932 or one or more applications 934 or a combination. OS 932, applications 934, and processes 936 provide software logic to provide functions for system 900. In one example, memory subsystem 920 includes memory controller 922, which is a memory controller to generate and issue commands to memory 930. It will be understood that memory controller 922 could be a physical part of processor 910 or a physical part of interface 912. For example, memory controller 922 can be an integrated memory controller, integrated onto a circuit with processor 910, such as integrated onto the processor die or a system on a chip.

While not specifically illustrated, it will be understood that system 900 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 900 includes interface 914, which can be coupled to interface 912. Interface 914 can be a lower speed interface than interface 912. In one example, interface 914 represents an interface circuit, which can include standalone components and integrated circuitry. In one example, multiple user interface components or peripheral components, or both, couple to interface 914. Network interface 950 provides system 900 the ability to communicate with remote devices (e.g., servers or other computing devices) over one or more networks. Network interface 950 can include an Ethernet adapter, wireless interconnection components, cellular network interconnection components, USB (universal serial bus), or other wired or wireless standards-based or proprietary interfaces. Network interface 950 can exchange data with a remote device, which can include sending data stored in memory or receiving data to be stored in memory.

In one example, system 900 includes one or more input/output (I/O) interface(s) 960. I/O interface 960 can include one or more interface components through which a user interacts with system 900 (e.g., audio, alphanumeric, tactile/touch, or other interfacing). Peripheral interface 970 can include any hardware interface not specifically mentioned above. Peripherals refer generally to devices that connect dependently to system 900. A dependent connection is one where system 900 provides the software platform or hardware platform or both on which operation executes, and with which a user interacts.

In one example, system 900 includes storage subsystem 980 to store data in a nonvolatile manner In one example, in certain system implementations, at least certain components of storage 980 can overlap with components of memory subsystem 920. Storage subsystem 980 includes storage device(s) 984, which can be or include any conventional medium for storing large amounts of data in a nonvolatile manner, such as one or more magnetic, solid state, or optical based disks, or a combination. Storage 984 holds code or instructions and data 986 in a persistent state (i.e., the value is retained despite interruption of power to system 900). Storage 984 can be generically considered to be a “memory,” although memory 930 is typically the executing or operating memory to provide instructions to processor 910. Whereas storage 984 is nonvolatile, memory 930 can include volatile memory (i.e., the value or state of the data is indeterminate if power is interrupted to system 900). In one example, storage subsystem 980 includes controller 982 to interface with storage 984. In one example controller 982 is a physical part of interface 914 or processor 910, or can include circuits or logic in both processor 910 and interface 914.

Power source 902 provides power to the components of system 900. More specifically, power source 902 typically interfaces to one or multiple power supplies 904 in system 900 to provide power to the components of system 900. In one example, power supply 904 includes an AC to DC (alternating current to direct current) adapter to plug into a wall outlet. Such AC power can be renewable energy (e.g., solar power) power source 902. In one example, power source 902 includes a DC power source, such as an external AC to DC converter. In one example, power source 902 or power supply 904 includes wireless charging hardware to charge via proximity to a charging field. In one example, power source 902 can include an internal battery or fuel cell source.

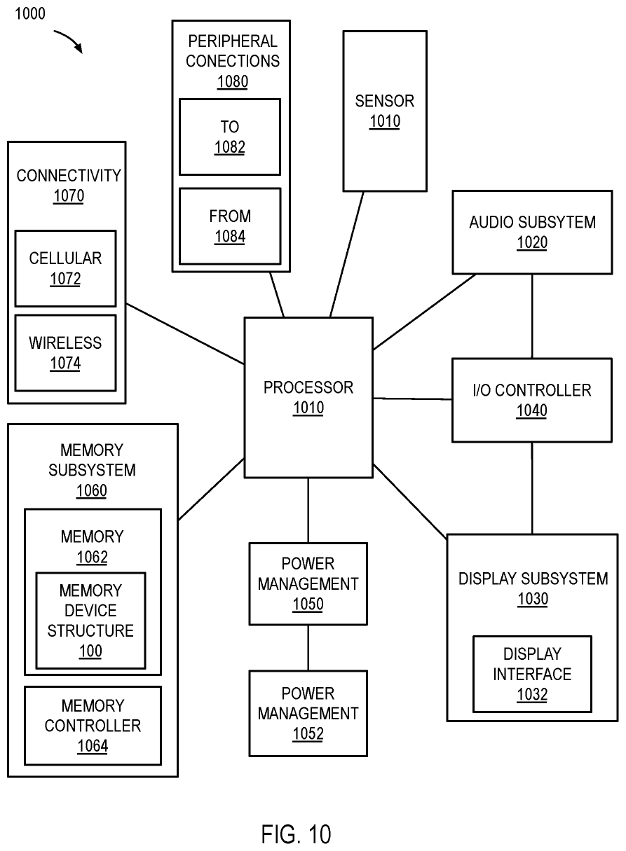

FIG. 10 is a block diagram of an example of a system 1000 that includes memory device structure to enable decoder transistor footprint scaling. System 1000 represents a mobile computing device, such as a computing tablet, a mobile phone or smartphone, wearable computing device, or other mobile device, or an embedded computing device. It will be understood that certain of the components are shown generally, and not all components of such a device are shown in system 1000.

Memory 1062 includes memory device structure 100, such as is described in association with FIG. 1A. Referring again to FIG. 10, the memory device structure 100 enables memory 1062 to provide selection of a target cell within the memory array. The use of the described memory device structure 100 enables selection with lower energy usage as compared to traditional decoder transistors.

System 1000 includes processor 1010, which performs the primary processing operations of system 1000. Processor 1010 can include one or more physical devices, such as microprocessors, application processors, microcontrollers, programmable logic devices, or other processing means. The processing operations performed by processor 1010 include the execution of an operating platform or operating system on which applications and device functions are executed. The processing operations include operations related to I/O (input/output) with a human user or with other devices, operations related to power management, operations related to connecting system 1000 to another device, or a combination. The processing operations can also include operations related to audio I/O, display I/O, or other interfacing, or a combination. Processor 1010 can execute data stored in memory. Processor 1010 can write or edit data stored in memory.

In one example, system 1000 includes one or more sensors 1012. Sensors 1012 represent embedded sensors or interfaces to external sensors, or a combination. Sensors 1012 enable system 1000 to monitor or detect one or more conditions of an environment or a device in which system 1000 is implemented. Sensors 1012 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 1012 can also include sensors for biometric systems such as fingerprint recognition systems, face detection or recognition systems, or other systems that detect or recognize user features. Sensors 1012 should be understood broadly, and not limiting on the many different types of sensors that could be implemented with system 1000. In one example, one or more sensors 1012 couples to processor 1010 via a frontend circuit integrated with processor 1010. In one example, one or more sensors 1012 couples to processor 1010 via another component of system 1000.

In one example, system 1000 includes audio subsystem 1020, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into system 1000, or connected to system 1000. In one example, a user interacts with system 1000 by providing audio commands that are received and processed by processor 1010.

Display subsystem 1030 represents hardware (e.g., display devices) and software components (e.g., drivers) that provide a visual display for presentation to a user. In one example, the display includes tactile components or touchscreen elements for a user to interact with the computing device. Display subsystem 1030 includes display interface 1032, which includes the particular screen or hardware device used to provide a display to a user. In one example, display interface 1032 includes logic separate from processor 1010 (such as a graphics processor) to perform at least some processing related to the display. In one example, display subsystem 1030 includes a touchscreen device that provides both output and input to a user. In one example, display subsystem 1030 includes a high definition (HD) or ultra-high definition (UHD) display that provides an output to a user. In one example, display subsystem includes or drives a touchscreen display. In one example, display subsystem 1030 generates display information based on data stored in memory or based on operations executed by processor 1010 or both.

I/O controller 1040 represents hardware devices and software components related to interaction with a user. I/O controller 1040 can operate to manage hardware that is part of audio subsystem 1020, or display subsystem 1030, or both. Additionally, I/O controller 1040 illustrates a connection point for additional devices that connect to system 1000 through which a user might interact with the system. For example, devices that can be attached to system 1000 might include microphone devices, speaker or stereo systems, video systems or other display device, keyboard or keypad devices, or other I/O devices for use with specific applications such as card readers or other devices.

As mentioned above, I/O controller 1040 can interact with audio subsystem 1020 or display subsystem 1030 or both. For example, input through a microphone or other audio device can provide input or commands for one or more applications or functions of system 1000. Additionally, audio output can be provided instead of or in addition to display output. In another example, if display subsystem includes a touchscreen, the display device also acts as an input device, which can be at least partially managed by I/O controller 1040. There can also be additional buttons or switches on system 1000 to provide I/O functions managed by I/O controller 1040.

In one example, I/O controller 1040 manages devices such as accelerometers, cameras, light sensors or other environmental sensors, gyroscopes, global positioning system (GPS), or other hardware that can be included in system 1000, or sensors 1012. The input can be part of direct user interaction, as well as providing environmental input to the system to influence its operations (such as filtering for noise, adjusting displays for brightness detection, applying a flash for a camera, or other features).

In one example, system 1000 includes power management 1050 that manages battery power usage, charging of the battery, and features related to power saving operation. Power management 1050 manages power from power source 1052, which provides power to the components of system 1000. In one example, power source 1052 includes an AC to DC (alternating current to direct current) adapter to plug into a wall outlet. Such AC power can be renewable energy (e.g., solar power, motion based power). In one example, power source 1052 includes only DC power, which can be provided by a DC power source, such as an external AC to DC converter. In one example, power source 1052 includes wireless charging hardware to charge via proximity to a charging field. In one example, power source 1052 can include an internal battery or fuel cell source.

Memory subsystem 1060 includes memory device(s) 1062 for storing information in system 1000. Memory subsystem 1060 can include nonvolatile (state does not change if power to the memory device is interrupted) or volatile (state is indeterminate if power to the memory device is interrupted) memory devices, or a combination. Memory 1060 can store application data, user data, music, photos, documents, or other data, as well as system data (whether long-term or temporary) related to the execution of the applications and functions of system 1000. In one example, memory subsystem 1060 includes memory controller 1064 (which could also be considered part of the control of system 1000, and could potentially be considered part of processor 1010). Memory controller 1064 includes a scheduler to generate and issue commands to control access to memory device 1062.

Connectivity 1070 includes hardware devices (e.g., wireless or wired connectors and communication hardware, or a combination of wired and wireless hardware) and software components (e.g., drivers, protocol stacks) to enable system 1000 to communicate with external devices. The external device could be separate devices, such as other computing devices, wireless access points or base stations, as well as peripherals such as headsets, printers, or other devices. In one example, system 1000 exchanges data with an external device for storage in memory or for display on a display device. The exchanged data can include data to be stored in memory, or data already stored in memory, to read, write, or edit data.

Connectivity 1070 can include multiple different types of connectivity. To generalize, system 1000 is illustrated with cellular connectivity 1072 and wireless connectivity 1074. Cellular connectivity 1072 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 1074 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 1080 include hardware interfaces and connectors, as well as software components (e.g., drivers, protocol stacks) to make peripheral connections. It will be understood that system 1000 could both be a peripheral device (“to” 1082) to other computing devices, as well as have peripheral devices (“from” 1084) connected to it. System 1000 commonly has a “docking” connector to connect to other computing devices for purposes such as managing (e.g., downloading, uploading, changing, synchronizing) content on system 1000. Additionally, a docking connector can allow system 1000 to connect to certain peripherals that allow system 1000 to control content output, for example, to audiovisual or other systems.

In addition to a proprietary docking connector or other proprietary connection hardware, system 1000 can make peripheral connections 1080 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

Accordingly, one or more embodiments of the present disclosure relate generally to tier architecture for 3-D cross point memory and methods of fabrication.

In a first example a memory device structure includes a plurality of memory cells, where individual ones of the plurality of memory cells include a selector element in series with a non-volatile memory element between a first terminal and a second terminal. The memory device structure further includes a pair of first conductors within a first tier, where individual ones of the first conductors are coupled to the first terminal of a first adjacent pair of memory cells in a first row orthogonal to the first conductors. The memory device structure further includes a pair of second conductors within a second tier and parallel to the first conductors, where individual ones of the second conductors are coupled to the first terminal of a second adjacent pair of memory cells in a second row, below the first row. The memory device structure further includes a third conductor that extends between the first and second tiers, where the third conductor is between each of the pair of the first conductors and the pair of the second conductors, and is coupled to second terminals of both the first and second adjacent pairs of memory cells.

In second examples, for any of first examples, the memory device structure further includes a pair of fourth conductors within the first tier, where individual ones of the fourth conductors are coupled to the first terminal of a third adjacent pair of memory cells in the first row and a pair of fifth conductors within the second tier and parallel to the fourth conductors, where individual ones of the fifth conductors are coupled to the first terminal of a fourth adjacent pair of memory cells in the second row. A sixth conductor extends between the first and second tiers, where the sixth conductor is between each of the pair of the fourth conductors and the pair of fifth conductors, and is coupled to the second terminals of both the third and fourth adjacent pairs of memory cells, and a seventh conductor is coupled to both the third conductor and the sixth conductor on a first side of the first tier, opposite of the second tier.

In third examples, for any of the first through second examples, the first adjacent pair of memory cells includes a first memory cell and a second memory cell, where the third adjacent pair of memory cells includes a third memory cell and a fourth memory cell, where the second adjacent pair of memory cells includes a fifth memory cell and sixth memory cell and where the fourth adjacent pair of memory cells includes a seventh and an eighth memory cell.

In fourth examples, for any of the first through third examples, the third conductor and the sixth conductor each has a sidewall that is co-planar with a sidewall of at least one of the first, the second, the third, the fourth, the fifth, the sixth, the seventh or the eighth memory cells

In fifth examples, for any of the first through fourth examples, a first one of the pair of first conductors is coupled to a first one of the pair of fourth conductors through a first lateral extension on a first side of the first row, and where a second one of the pair of first conductors is coupled to a second one of the pair of fourth conductors through a second lateral extension on a second side of the first row, opposite of the first lateral extension, and where each of the first and the second lateral extensions have a longitudinal axis that is parallel to the first row.

In sixth examples, for any of the first through fifth examples, a first one of the pair of second conductors is coupled to a first one of the pair of fifth conductors through a first lateral extension on a first side of the second row, and where a second one of the pair of second conductors is coupled to a second one of the pair of fifth conductors through a second lateral extension on a second side of the second row, opposite to the first lateral extension, and where each of the first and second lateral extensions have a longitudinal axis that is parallel to the second row.

In seventh examples, for any of the first through sixth examples, the seventh conductor extends laterally above a first one of the pair of first conductors and a first one of the pair of fourth conductors.

In eighth examples, for any of the first through seventh examples, a selector element directly adjacent to the first terminal and to the non-volatile memory element is directly adjacent to the second terminal.

In ninth examples, for any of the first through eighth examples, the third conductor and the sixth conductor are each a via pillar.

In tenth examples, for any of the first through ninth examples, the first tier is vertically separated from the second tier by a distance between 5 nm and 30 nm.

In eleventh examples, for any of the first through tenth examples, the each of the first tier and the second tier have a vertical thickness between 5 nm and 20 nm.

In twelfth examples, for any of the first through eleventh examples, the individual ones of plurality of memory cells each have a lateral width along the first or the second row that is less than 125 nm.

In thirteenth examples, for any of the first through twelfth examples, the memory cell further includes a third terminal that electrically couples the non-volatile memory element to the selector element, where the third terminal has a lateral width along the first or the second row that is between a monolayer and 10 nm.

In a fourteenth example, for any of the first through thirteenth examples, individual ones of the fifth conductors and the sixth conductors have a lateral width along the first or the second row that is between 40 nm and 70 nm.

In a fifteenth example, a method of fabricating a memory device, includes forming plurality of openings in a material layer stack including a plurality of bilayers, where each of the plurality of bilayers includes a first dielectric above a second dielectric. The method further includes laterally recessing a portion of the second dielectric within the plurality of openings to form lateral recesses and forming layers of a selector element within the lateral recesses. The method further includes forming layers of a memory element within the lateral recesses adjacent to the selector element and etching layers of the memory element and of the selector element to isolate a plurality of memory cells, each of the memory cells including one of the memory elements adjacent to one of the selector elements and forming electrodes adjacent to the plurality of memory cells.

In a sixteenth example, for any of the fifteenth examples, forming the electrodes includes removing the second dielectric from each of the plurality of bilayers and depositing a first electrode material adjacent to a first terminal of each of the plurality of memory cells.

In seventeenth examples, for any of the fifteenth through fifteenth examples, forming the electrodes further includes forming a second electrode between a second terminal of adjacent pairs of the plurality of memory cells.

In eighteenth examples, for any of the fifteenth through sixteenth examples, etching the layers to isolate the plurality of memory cells includes forming sidewalls of the memory cells, and wherein a sidewall of the selector element is co-planar with a sidewall of the memory element.

In nineteenth examples, a system includes a processor and a memory device. The memory device structure includes a plurality of memory cells, where individual ones of the plurality include a selector element in series with a non-volatile memory element between a first terminal and a second terminal. The memory device structure further includes a pair of first conductors within a first tier, where individual ones of the first conductors are coupled to the first terminal of a first adjacent pair of memory cells in a first row orthogonal to the first conductors. The memory device structure further includes a pair of second conductors within a second tier and parallel to the first conductors, where individual ones of the second conductors are coupled to the first terminal of a second adjacent pair of memory cells in a second row, below the first row. The memory device structure further includes a third conductor that extends between the first and second tiers, where the third conductor is between each of the pair of the first conductors and the pair of the second conductors, and is coupled to second terminals of both the first and second adjacent pairs of memory cells.

In twentieth example, for any of the nineteenth examples, the system further includes a memory controller coupled with the memory device structure.

What is claimed is:

1. A memory device structure, comprising:
a plurality of memory cells, wherein individual ones of the plurality of memory cells comprise a selector element in series with a non-volatile memory element between a first terminal and a second terminal;
a pair of first conductors within a first tier, wherein individual ones of the first conductors are coupled to the first terminal of a first adjacent pair of the memory cells in a first row orthogonal to the first conductors;
a pair of second conductors within a second tier and parallel to the first conductors, wherein individual ones of the second conductors are coupled to the first terminal of a second adjacent pair of memory cells in a second row, below the first row; and
a third conductor that extends between the first and second tiers, wherein the third conductor is between each of the pair of the first conductors and the pair of the second conductors, and is coupled to second terminals of both the first and second adjacent pairs of memory cells.

2. The memory device structure of claim 1, further comprising:
a pair of fourth conductors within the first tier, wherein individual ones of the fourth conductors are coupled to the first terminal of a third adjacent pair of memory cells in the first row;
a pair of fifth conductors within the second tier and parallel to the fourth conductors, wherein individual ones of the fifth conductors are coupled to the first terminal of a fourth adjacent pair of memory cells in the second row;
a sixth conductor that extends between the first and second tiers, wherein the sixth conductor is between each of the pair of the fourth conductors and the pair of fifth conductors, and is coupled to the second terminals of both the third and fourth adjacent pairs of memory cells; and
a seventh conductor coupled to both the third conductor and the sixth conductor on a first side of the first tier, opposite of the second tier.

3. The memory device structure of claim 2, wherein the first adjacent pair of memory cells comprises a first memory cell and a second memory cell, wherein the third adjacent pair of memory cells comprises a third memory cell and a fourth memory cell, wherein the second adjacent pair of memory cells comprises a fifth memory cell and sixth memory cell and wherein the fourth adjacent pair of memory cells comprises a seventh and an eighth memory cell.

4. The memory device structure of claim 3, wherein the third conductor and the sixth conductor each has a sidewall that is co-planar with a sidewall of at least one of the first, the second, the third, the fourth, the fifth, the sixth, the seventh or the eighth memory cells.

5. The memory device structure of claim 2, wherein a first one of the pair of first conductors is coupled to a first one of the pair of fourth conductors through a first lateral extension on a first side of the first row, and wherein a second one of the pair of first conductors is coupled to a second one of the pair of fourth conductors through a second lateral extension on a second side of the first row, opposite of the first lateral extension, and wherein each of the first and the second lateral extensions have a longitudinal axis that is parallel to the first row.

6. The memory device structure of claim 2, wherein a first one of the pair of second conductors is coupled to a first one of the pair of fifth conductors through a first lateral extension on a first side of the second row, and wherein a second one of the pair of second conductors is coupled to a second one of the pair of fifth conductors through a second lateral extension on a second side of the second row, opposite to the first lateral extension, and wherein each of the first and second lateral extensions have a longitudinal axis that is parallel to the second row.

7. The memory device structure of claim 2, wherein the seventh conductor extends laterally above a first one of the pair of first conductors and a first one of the pair of fourth conductors.

8. The memory device structure of claim 2, wherein a selector element directly adjacent to the first terminal and to the non-volatile memory element is directly adjacent to the second terminal.

9. The memory device structure of claim 2, wherein the third conductor and the sixth conductor are each a via pillar.

10. The memory device structure of claim 1, wherein the first tier is vertically separated from the second tier by a distance between 5 nm and 30 nm.

11. The memory device structure of claim 1, wherein the each of the first tier and the second tier have a vertical thickness between 5 nm and 20 nm.

12. The memory device structure of claim 1, wherein the individual ones of plurality of memory cells each have a lateral width along the first or the second row that is less than 125 nm.

13. The memory device structure of claim 1, wherein the memory cell further comprises a third terminal that electrically couples the non-volatile memory element to the selector element, wherein the third terminal has a lateral width along the first or the second row that is between a monolayer and 10 nm.

14. The memory device structure of claim 2, wherein individual ones of the fifth conductors and the sixth conductors have a lateral width along the first or the second row that is between 40 nm and 70 nm.

15. A method of fabricating a memory device, comprising:
forming a plurality of openings in a material layer stack comprising a plurality of bilayers, wherein each of the plurality of bilayers comprises a first dielectric above a second dielectric;
laterally recessing a portion of the second dielectric within the plurality of openings to form lateral recesses;
forming layers of a selector element within the lateral recesses;
forming layers of a memory element within the lateral recesses adjacent to the selector element;
etching layers of the memory element and of the selector element to isolate a plurality of memory cells, each of the memory cells comprising one of the memory elements adjacent to one of the selector elements; and
forming electrodes adjacent to the plurality of memory cells.

16. The method of claim 15, wherein forming the electrodes includes removing the second dielectric from each of the plurality of bilayers and depositing a first electrode material adjacent to a first terminal of each of the plurality of memory cells.

17. The method of claim 16, wherein forming the electrodes further comprises forming a second electrode between a second terminal of adjacent pairs of the plurality of memory cells.

18. The method of claim 15, wherein etching the layers to isolate the plurality of memory cells includes forming sidewalls of the memory cells, and wherein a sidewall of the selector element is co-planar with a sidewall of the memory element.

19. A system comprising:
a processor; and
a memory device, comprising:
a plurality of memory cells, wherein individual ones of the plurality comprise a selector element in series with a non-volatile memory element between a first terminal and a second terminal;
a pair of first conductors within a first tier, wherein individual ones of the first conductors are coupled to the first terminal of a first adjacent pair of memory cells in a first row orthogonal to the first conductors;
a pair of second conductors within a second tier and parallel to the first conductors, wherein individual ones of the second conductors are coupled to the first terminal of a second adjacent pair of memory cells in a second row, below the first row; and
a third conductor that extends between the first and second tiers, wherein the third conductor is between each of the pair of the first conductors and the pair of the second conductors, and is coupled to second terminals of both the first and second adjacent pairs of memory cells.

20. The system of claim 19, further comprises a memory controller coupled with the memory device structure.
